(19) United States
(12) Patent Application Publication
(10) Pub. No.: US 2026/0107391 A1
(43) Pub. Date: Apr. 16, 2026

(54) ADDITIVELY MANUFACTURED ELECTRONICS PACKAGING WITH INTEGRATED LEAK DETECTION CIRCUIT

(71) Applicant: Raytheon Company, Arlington, VA (US)

(72) Inventors: Fernando Ma, Tucson, AZ (US); Mark R. Northrup, Marana, AZ (US)

(21) Appl. No.: 19/310,659

(22) Filed: Aug. 26, 2025

Related U.S. Application Data
(60) Provisional application No. 63/706,405, filed on Oct. 11, 2024.

(51) Int. Cl. H05K 5/00; B22F 10/00; B28B 1/00; B29C 64/10; B29L 31/34; B33Y 10/00; B33Y 80/00; C03B 19/00; G01M 3/16; H05K 3/46; H05K 5/06

(52) U.S. Cl. CPC H05K 5/0047; B22F 10/00; B28B 1/001; B29C 64/10; B33Y 10/00; B33Y 80/00; C03B 19/00; G01M 3/165; H05K 3/4664; H05K 5/06; B29L 2031/3406

(57) ABSTRACT

An additively manufactured electronics packaging assembly including a build substrate formed from a plurality of additively printed layers. One or more additively printed electrical interconnects can be positioned within the plurality of layers. The assembly can include an electronics housing built along the build substrate. The electronics housing can include one or more additively printed walls extending around a component cavity and a housing lid enclosing and sealing the cavity. One or more additively printed electrical circuits can be included within the component cavity, which can be electrically connected with the additively printed electrical interconnects. One or more electronic components can be positioned within the cavity and can be electrically connected to the additively printed electrical interconnects. The additively printed electrical circuits can be used to indicate a leak in the additively manufactured electronics packaging assembly.

### BACKGROUND

Additive manufacturing, also known as 3D printing, is a manufacturing process that forms three-dimensional objects by depositing materials layer by layer until a final product is built. This technique contrasts with traditional subtractive manufacturing methods, which typically involve cutting away material from a larger block. For example, in additive manufacturing layers of material are built up, layer by layer, according to designs generated with computer-aided design technology. During the build up of material, voids, recesses, cavities and the like are formed by not printing materials in those areas.

In some examples, an additively manufactured product is formed by designing a computer model of the desired final product. The design is converted to a format that can be communicated to a 3D printer. The 3D printer can be instructed to deposit, or print, material, layer by layer, according to the locations indicated in the computer model. In some examples, the 3D printer forms solid structures, porous structures or structures having openings or cavities. In other examples, the 3D printer prints products having enclosed cavities. The 3D printer can also print components for a final product; for example, components are coupled with separate 3D printed components or components that have not been 3D printed.

Some examples of additive manufacturing, or 3D printing, technologies include fused deposition modeling (FDM), stereolithography (SLA), selective laser sintering (SLS), direct metal laser sintering (DMLS), binder jetting, syringe printing and aerosol-jet printing. This list is not an exhaustive list of additive manufacturing technologies, but an example of methods implemented to manufacture products by a repeated addition of material. In some examples, a combination of methods can be used to form an additively manufactured product.

Fused deposition modeling is, for example, a process that includes melting filaments, such as polymers, metals, ceramics, glass or the like. The melted filaments are then extruded from a nozzle. In an example, the extruded, melted filaments are deposited layer by layer on a plate. Each layer is subsequently placed on a previous layer according to the design communicated to the 3D printer.

Stereolithography is a form of 3D printing that uses a photochemical process. A light is applied to chemicals to cross-link and form polymers. In some examples, an ultraviolet (UV) light is focused on a polymer resin. As the light is applied to the polymer, the polymer solidifies. The polymers are bonded to, for example, form a three-dimensional solid.

Selective Laser Sintering (SLS) is an additive manufacturing technique that uses, for example, a high-power laser to selectively fuse powdered materials into a desired three-dimensional shape. In this process, a thin layer of powder can be spread over a build platform. The laser then traces the cross-section of the object being built, sintering the powder particles and bonding them together. In some examples, the powdered material is a metal, ceramic, polymer or glass.

Binder Jetting is an example of an additive manufacturing process that can be used to form three-dimensional objects by selectively depositing a liquid binding agent onto layers of powder material. In this technique, a print head moves across a bed of powder, applying droplets of binder to bond the particles together in the desired shape. This process can repeat layer by layer until the entire object is formed. Once the printing is complete, the part can be cured to strengthen the bonds between particles.

Syringe printing and aerosol-jet printing are examples of an additive manufacturing process that can be used to form electrically conductive traces (e.g., electrical circuits) on a substrate. For example, electrically conductive ink can be atomized to create an aerosol, which is then carried to a deposition head using a carrier gas. The aerosol can be focused into a print beam using another gas.

Additive manufacturing can be used in a wide range of industries due to its versatility and ability to form complex geometries. For example, in the military, aerospace and defense sectors, additive manufacturing can be used for producing lightweight components and components that can withstand harsh environments. In another example, the automotive industry leverages additive manufacturing for rapid prototyping and creating specialized parts. Additionally, additive manufacturing can be utilized in the oil and gas industry for forming specialized tools and components that can operate in challenging conditions. The marine industry can also benefit from additive manufacturing technology for producing corrosion-resistant parts. In another example, additive manufacturing also is applicable in consumer goods, allowing for personalized products and reducing waste in manufacturing processes.

### SUMMARY

An additively manufactured electronics packaging with an integrated leak detection circuit can address challenges in some currently implemented electronics packaging technologies. For example, an additively manufactured electronics packaging can reduce potential environmental effects and leak paths of a sealed electrical package. In other examples, the additively manufactured electronics packaging can be implemented in systems that can be subject to harsh environments. An integrated leak detection circuit can provide in situ leak testing of the additively manufactured electronics packaging.

For example, an additively manufactured electronics packaging assembly can include a build substrate formed from one or more additively printed layers. In some examples, the additively manufactured electronics packaging assembly can include one or more additively printed layers that can incorporate, include, one or more electrical interconnects, or form one or more electrical traces. The one or more electrical interconnects can be positioned within the one or more additively printed layers during the process of printing the one or more additively printed layers. For example, an additively manufactured build substrate, or foundation of the additively manufactured electronics packaging, can include printed layers that can include additively printed electrical interconnects, or traces, which are positioned within the build substrate.

The additively manufactured electronics packaging assembly can include an electronics housing coupled to the build substrate. In an example, the electronics housing is combined with the build substrate. For example, the electronics housing can be additively manufactured as a unitary structure with the additively manufactured build substrate. The electronics housing can be formed from additively printed walls extending around a component cavity. The component cavity can be formed to house, retain, position or the like any of a number of electrical components within the electronics housing. In an example, a leak detection circuit can be additively printed on the additively manufactured build substrate within the component cavity. The leak detection circuit can be electrically connected to at least one portion of an additively printed electrical interconnect. In an example, one or more electronic components positioned within the component cavity are electrically connected to at least one portion of an additively printed electrical interconnect.

A housing lid can be coupled with one or more of the additively printed walls and can enclose the component cavity. The housing lid can be an additively manufactured component. In another example the housing lid can be formed by molding, extruding, or other method.

The additively printed electronics packaging assembly can seal the additively printed leak detection circuit and the electronic components positioned within the additively printed electronics housing from the external environment. In an example, the additively printed walls extend from the build substrate. In another example, the housing lid is coupled, adhered, or additively printed on the one or more additively printed walls to form a sealed environment within the component cavity. For example, the arrangement of the one or more additively printed walls and the housing lid coupled with the additively printed walls seals the one or more electrical components within the electronics housing. The additively printed leak detection circuit can be used to characterize the interior environment of the additively printed electronics housing once the housing lid seals the additively printed leak detection circuit and the electrical components within the electronics housing.

The above and following description, while indicating various examples of the concepts, is given by way of illustration and not of limitation. Many substitutions, modifications, additions or rearrangements may be made within the scope of the disclosed examples, and the examples discusses can include substitutions, modifications, additions or rearrangements.

### BRIEF DESCRIPTION OF THE DRAWINGS

FIGS. 1A and 1B illustrate examples of a schematic of an additively manufactured electronics packaging according to at least one example of the present disclosure.

FIG. 2 illustrates an example of a schematic additively manufactured electronics packaging assembly according at least one example of the present disclosure.

FIG. 3 illustrates an example of a method of forming an additively manufactured electronics packaging assembly according to at least one example of the present disclosure.

FIG. 4 illustrates an example of an electrical circuit diagram for an electrical circuit that can be additively printed with an additively manufactured electronics packaging assembly.

FIG. 5 illustrates an example of an interdigitated capacitor that can be additively printed in an additively printed electrical circuit.

FIG. 6 illustrates a system for detecting degradation of a hermetic seal in an additively manufactured electronics packaging assembly.

### DETAILED DESCRIPTION

Computer chips, electronic components and the like can employ packaged technology to provide an electronics systems that can be used to implement an overall system. For example, an electronics packaging can be an enclosure for electronic devices to protect electrical components. Electronic packages can protect electronic components, for example, capacitors, resistors, memory systems, and electrical interconnects from the exterior environment. In some examples, such as a semiconductor package, the design can be implemented to protect individual components that are fabricated on substrates (e.g., wafers, silicon, glass). The electronics packaging can provide a way of connecting the components to another system, such as a printed circuit board.

In some examples, the electronics packaging includes several components formed from one or more materials. For instance, a hybrid electronic packaging is a package that combines active chip devices with passive components. In some examples, the components are electrically insulated from the outer environment such that they are packaged in a hermetically sealed environment. For example, the internal components are housed in a low-pressure environment that has been sealed to minimize infiltration from external environmental material such as particulates, moisture or the like that can inhibit, damage or destroy the operation of the internal electrical components.

In some examples, the seal is a hermetic seal that is capable of maintaining a low-pressure environment or electrical insulation. In some situations, the hermetic seal can be subject to degradation. Degradation of the hermetic seal can cause failures in the electronic system, packaging or the like. For example, an improper seal can cause electrical signal leakage, change the internal environment of the electronic packaging, or allow infiltration of environmental material into the packaging. In other examples, failures in the electronics package can occur at interfaces between structural components of the electronics package. For instance, there can be a leak path at the interface between a lid or at intersection of the electronic housing or frame components with the substrate.

In some examples, leak testing a packaged system can include external testing apparatus. For example, to determine if the hermetic seal has degraded, a helium leak detection test can be performed, which can include techniques such as mass spectrometry, residual gas analysis, radioisotope testing, or the like. Operating the external testing apparatus can be time intensive, which can lead to sparse sampling of a batch of packaged devices. In an example, an electrical leak detection circuit can be included alongside the electronic devices. For example, an electrical leak detection circuit can be hermetically sealed and can be responsive in one or more electrical characteristics to a pressure, humidity, temperature, or the like, of the low-pressure environment.

Some examples of a packaging system can include additively manufacturing at least a component of the electronics packaging. For example, additive manufacturing, or 3D printing, is implemented to form a build substrate as the foundational component of the electronics packaging. Other components of the electronics packaging can then be coupled, attached, adhered, fastened, inserted, or included in or with the build substrate. In an example, the electrical leak detection circuit can be additively manufactured or additively printed with the build substrate. In some examples, the majority of the electronics package is formed from an additive manufacturing process.

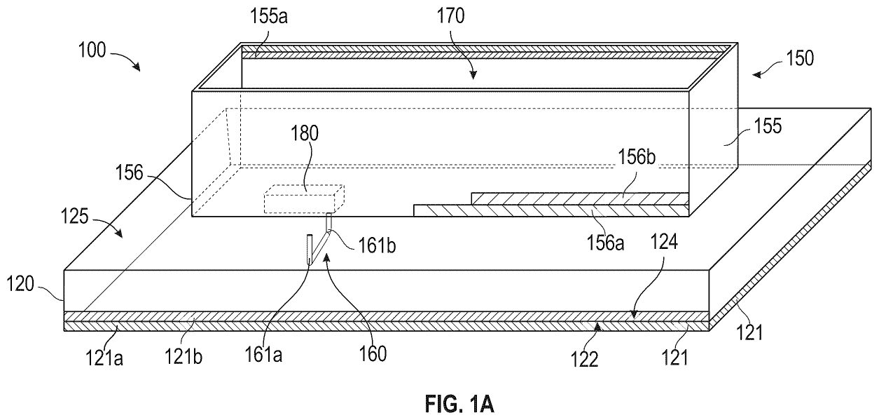

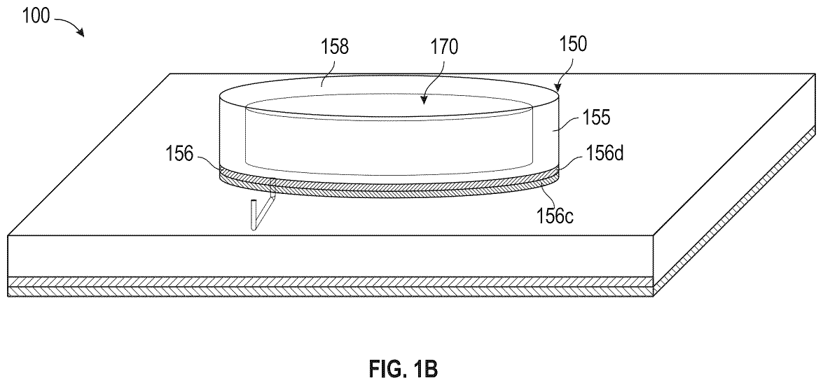

Illustrated in FIG. 1A is an example of an additively manufactured electronics packaging 100. The additively manufactured electronics packaging 100 can include a build substrate 120 as a foundational or base component. The build substrate 120 can support additional components of the additively manufactured electronics packaging 100. The build substrate 120 can support an electronics housing 150. The build substrate 120 can support one or more electrical interconnects 160. The build substrate 120 can also support one or more additively printed electrical circuits 180.

In an example, the additively manufacture build substrate 120 includes one or more additively printed layers 121. The one or more additively printed layers 121 can be formed from one or more of ceramic, glass, metal or polymer. For example, the one or more additively printed layers 121 can include ceramic. In another example, the one or more additively printed layers 121 can include a first additively printed layer 121a that includes a ceramic and a second additively printed layer 121b that includes a polymer. In yet another example, the one or more additively printed layers 121 can include a first additively printed layer 121a that includes a ceramic and a second additively printed layer 121b that includes a metal. Optionally, the additively printed layers 121 can include one or more of first additively printed layer 121a stacked, or layered, on another followed by one or more of second additively printed layer 121b. Including multiple one or more additively printed layers 121 formed from any number of different materials can also be implemented informing the build substrate 120.

The first additively printed layer 121a can include a first layer interface 122 as an outer facing surface of the first additively printed layer 121a. The first layer interface 122 can be positioned to face the second additively printed layer 121b. The second additively printed layer 121b can include a second layer interface 124 as an outer facing surface of the second additively printed layer 121b. The first additively printed layer 121a and the second additively printed layer 121b are, for example, oriented with the second additively printed layer 121b to join with the first additively printed layer 121a. For instance, the second layer interface 124 is deposited (e.g., additively printed) to be intermingled with the first layer interface 122. In examples, subsequent one or more additively printed layers 121 are repeatedly deposited on a previously deposited one or more additively printed layers 121 until the form of the build substrate 120 is completed or reaches a predetermined structure.

The position where the one or more additively printed layers 121 (e.g., subsequent first additively printed layers and second additively printed layers) meet, join, or are otherwise coupled, the one or more additively printed layers 121 can be intermingled. Intermingling of the one or more additively printed layers 121 can include a fluid, liquid or powder deposition of additively printed material at least partially combining or joining with the previously deposited additively printed layer. For example, at least some of the subsequent deposited additively printed layer (e.g., the second additively printed layer 121b) is welded, fused, bonded with the previously deposited (e.g., the first additively printed layer 121a).

In an example, the one or more additively printed layers 121 includes additively printed insulating layers. For example, the one or more additively printed layers 121 includes materials that are electrically insulating such that electricity flowing through the additively printed material as part of the electronics packaging are protected from the external environment.

In an example, the one or more additively printed layers 121 includes additively printed insulating layers that has one or more additively printed electrical interconnects 160, or traces that can support an electrical interface. For instance, the one or more electrical interconnects 160 is integrated within the one or more additively printed layers 121. The one or more electrical interconnects 160, as additively printed electrical interconnects, can be printed in concert to printing, or depositing, the one or more additively printed layers 121. For example, the one or more electrical interconnects 160 can be printed to be positioned at predetermined locations of a layer instead of the additively printed layer 121 material. The one or more electrical interconnects 160 can be additively printed within one layer of the one or more additively printed layers 121. In another example, the one or more electrical interconnects 160 is printed to extend through more than one layer of the one or more additively printed layers 121.

The one or more electrical interconnects 160 can include a first end portion 161a and a second end portion 161b. The first end portion 161a and the second end portion 161b can extend through more than one layer of the one or more additively printed layers 121. In an example, at least part of one of the first end portion 161a or the second end portion 161b is additively printed to extend through more than one layer of the one or more additively printed layers 121 to be exposed from the build substrate 120. For instance, the first end portion 161a and the second end portion 161b are each additively printed to be coupled or connected with an electrical component.

The one or more electrical interconnects 160 can be printed as a deposition of a metal or a conductive adhesive, such that the one or more electrical interconnects 160 is integrated with the additively printed layer. For example, a deposition of copper, aluminum, nickel, alloys, or other metals that are suitable for the purpose can form the one or more electrical interconnects 160. In another example, a deposition of a conductive adhesive can include silver, graphite or other conductive material mixed with an adhesive.

An example of the additively manufactured electronics packaging 100 includes the electronics housing 150. The electronics housing 150, for example, is positioned on a surface 125 of the build substrate 120. For instance, the surface 125 is a top surface of the build substrate 120. The electronics housing 150 can be formed to be additively printed as an extension of the build substrate 120. In another example, the electronics housing 150 is additively printed from a different material such that it is coupled along the build substrate 120. The electronics housing 150 can be additively printed as a unitary structure with the build substrate 120. For example, the electronics housing 150 can be considered one structure without any breaks, gaps, recesses or the like, between the electronics housing 150 and the build substrate 120.

The electronics housing 150 can include one or more additively printed walls 155. The one or more additively printed walls 155 and at least one of the one or more additively printed layers 121 can be printed in concert. For example, at least one layer 156 of the one or more additively printed walls 155 can be printed continuously with the one or more additively printed layers 121 such that the one layer 156 is a continuous structure with the build substrate 120. In another example, the one layer 156 of the one or more additively printed walls 155 can be printed, or deposited, shortly after substantially completing printing the one or more additively printed layers 121, such as within a few minutes after, less than one minute after, less than five seconds after, less than one second after. In an example, the one layer 156 can be additively printed while the one or more additively printed layers 121 is still being additively printed. In even further examples, more than one layer of the additively the one or more additively printed walls 155 can be printed while other portions of the build substrate 120 are printed.

The one or more additively printed walls 155 can be printed as one continuous wall, such as a rounded form 158 (e.g., circle, ellipse, oval or the like) as illustrated in FIG. 1B. For example, in some situations the design of the electronics housing 150 includes a rounded form to reduce the number of corners of the electronics housing 150. In another example, the one or more additively printed walls 155 can be additively printed as a polygon as illustrated in the example additively manufactured electronics packaging 100 of FIG. 1A. For example, the one or more additively printed walls 155 are printed to form a rectangle. The one or more additively printed walls 155 can be printed according to the purpose of the electronics housing 150.

In some examples, the one or more additively printed walls 155 are printed using more than one material. For instance, the one or more additively printed walls 155 includes additively printed insulating layers, such as a dielectric material. The one or more additively printed walls 155 can include one layer 156 of a first wall layer 156a including a first insulating material and a second wall layer 156b of a second insulating material. The one or more additively printed walls 155 can be formed in a rounded form 158 that can include a first additively printed ring layer 156c and a second additively printed ring layer 156d. In an example, the first wall layer 156a or the first additively printed ring layer 156c can include a polymer, such as a dielectric material, and the second wall layer 156b or second additively printed ring layer 156d can include a ceramic material. In other examples, the one or more additively printed walls 155 (of any form) can include more interior wall layers 155a. Each of the one or more additively printed walls 155 and the more interior wall layers 155a can be formed, printed, or the like from the same material or different materials.

The one or more additively printed walls 155 can extend around a component cavity 170. For example, the one or more additively printed walls 155 can formed (e.g., deposited) to be spaced from opposing portions, or opposing walls. The one or more additively printed walls 155 can be positioned to surround, extend around, or define the component cavity 170 so one or more components can be housed, placed or the like within the component cavity 170. In an example, at least one end portion 161 of one or more electrical interconnects 160 can be within the component cavity 170. For example, as illustrated in FIG. 1A, second end portion 161b can be positioned inside the component cavity 170.

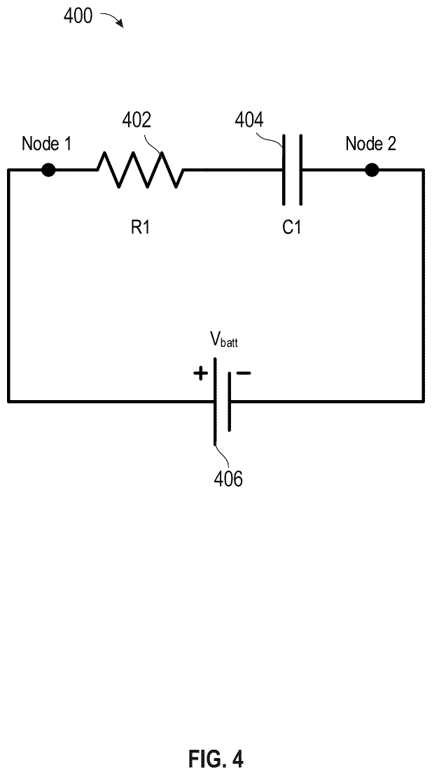

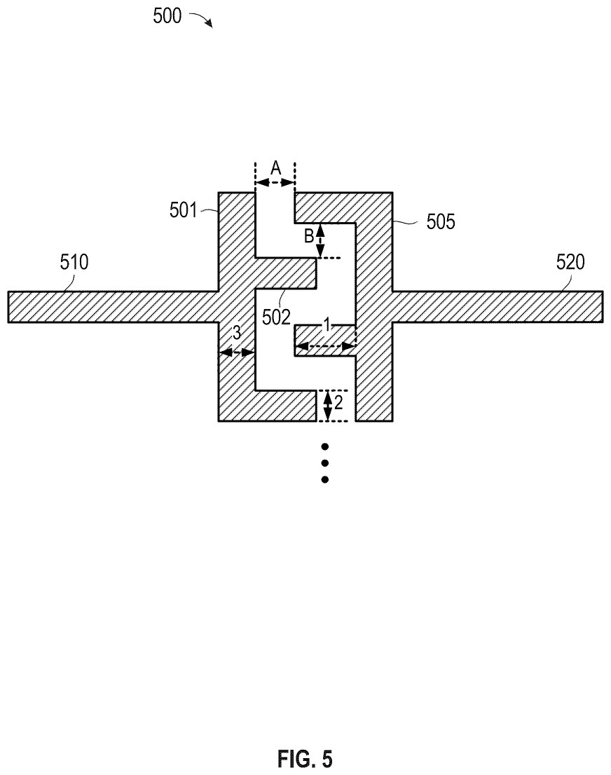

The component cavity 170 can include one or more additively printed electrical circuits 180. The one or more additively printed electrical circuits 180 can include one or more electrical components. For example, the one or more additively printed electrical circuits 180 can include a resistive component, a capacitive component, an inductive component, or a wire trace to connect different electrical components in the one or more additively printed electrical circuits 180. Further examples of electrical components that can be included in the one or more additively printed electrical circuits 180 are discussed below with reference to FIG. 4 and FIG. 5.

In an example, at least one electrical component in the one or more additively printed electrical circuits 180 can be responsive to a change in an environmental condition of the component cavity 170. For example, the one or more additively printed electrical circuits 180 can be responsive to changes in pressure, humidity, heat, or any combination thereof. Further examples of the use of the one or more additively printed electrical circuits 180 to detect changes in the environment of the component cavity 170 are discussed below with reference to FIG. 4 through FIG. 6.

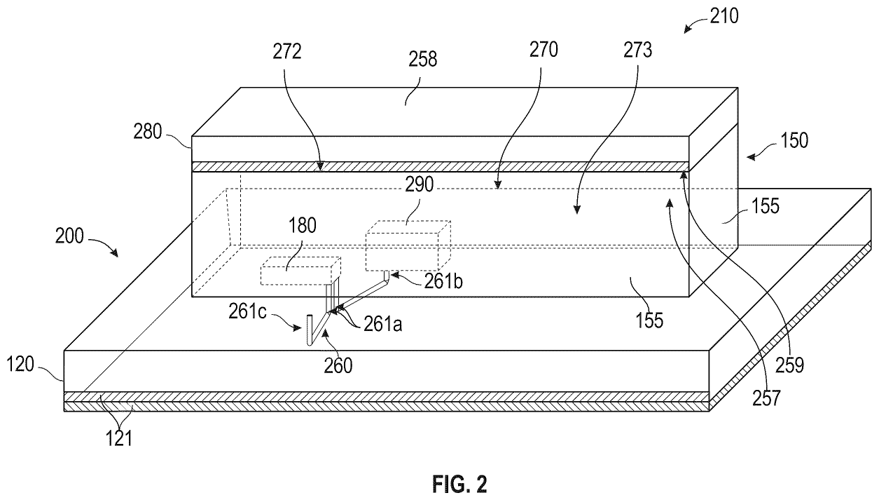

The one or more additively printed electrical circuits 180 can be positioned at specified locations within the component cavity 170. In an example, the one or more additively printed electrical circuits 180 can be printed planar or flush with the surface 125 of the build substrate 120. In an example, the one or more additively printed electrical circuits 180 can be printed on the surface 125 so as to be proud of the build substrate 120. In an example, the one or more additively printed electrical circuits 180 can be printed on the one or more additively printed walls 155. In an example, the one or more additively printed electrical circuits 180 can be printed on a surface of a lid of the housing (e.g., such as housing lid 258 discussed below with reference to FIG. 2), where the surface of the lid faces the interior of the electronics housing (e.g., the component cavity 170).

In an example, the one or more additively printed electrical circuits 180 can be printed to electrically contact one or more electrical interconnects 160. For example, as illustrated in FIG. 1A, second end portion 161b and the one or more additively printed electrical circuits 180 can be in electrical contact.

The one or more additively printed electrical circuits 180 can be printed as a deposition of a metal or a conductive adhesive, such that the one or more additively printed electrical circuits 180 is integrated with the additively printed layer. For example, a deposition of copper, aluminum, nickel, alloys, or other metals that are suitable for the purpose can form the additively printed electrical circuits 180. In another example, a deposition of a conductive adhesive can include silver, graphite or other conductive material mixed with an adhesive.

In an example, the one or more additively printed electrical circuits 180 and at least one of the additively printed layers 121 can be printed in concert. In an example, the one or more additively printed electrical circuits 180 and one or more additively printed walls 155 can be printed in concert. In an example, the one or more additively printed electrical circuits 180 and one or more additively printed electrical interconnects 160 can be printed in concert.

As illustrated in FIG. 2, the additively manufactured electronics packaging assembly 210 can include the build substrate 120 and the electronics housing 150 as a unitary structure. The electronics housing 150 can be coupled with the build substrate 120 such that the electronics housing 150 extends from the build substrate 120. In an example, the electronics housing 150 is combined with the build substrate 120. The electronics housing 150, for example, is printed, deposited, or otherwise additively manufactured in concert with the build substrate 120. For instance, a short time after (e.g., less than five minutes, less than one minute, less than ten seconds, less than one second) the build substrate 120 is completed (e.g., partially set, fully set, or the like) the electronics housing 150 is printed on the build substrate 120.

In an example, the electronics housing 150 is formed from one or more additively printed walls 155. The one or more additively printed walls 155 extend around a component cavity 270. The component cavity 270 can be a recess, opening, space or the like that has a profile that can house, store, receive or the like, one or more additively printed electrical circuits 180 (as discussed above with reference to the component cavity 170 and FIG. 1), and one or more electronic components 290.

The one or more electronic components 290 can include computer chip components (e.g., resistors, capacitors, memory, or the like) or optic devices such as photonics (e.g., laser sending and receiving devices). The one or more electronic components 290 can be positioned within the component cavity 270 at specified locations according to the purpose. In an example, the one or more electronic components 290 are electrically connected to one of the one or more additively printed electrical circuits 180. For example, the one or more electronic components 290 can be electrically connected to the one or more additively printed electrical circuits 180 such that a common power source (e.g., direct current (DC) power source, alternating current (AC) power source) can deliver electrical power to both of the one or more electronic components 290 and the additively printed electrical circuits 180. In an example, the one or more electronic components 290 are coupled with another of the one or more electronic components 290 or are coupled with elements external to the additively manufactured electronics packaging assembly 210.

In another example of an additively manufacture electronics packaging 200 illustrated in FIG. 2, the build substrate 120 can include one or more electrical interconnects 260. The one or more electrical interconnects 260 can be similar to the one or more electrical interconnects 160. For example, the one or more electrical interconnects 260 can be positioned, additively printed, disposed, deposited, integrated or the like within the build substrate 120. In another example, the build substrate 120 can be formed to include electrical traces where one or more electrical interconnects 260 can be positioned. Optionally, the one or more electrical interconnects 260 can be additively printed within or on the build substrate 120. For example, the one or more electrical interconnects 260 can be printed as a deposition of a metal or conductive adhesive integrated into the one or more electrical interconnects 160.

The one or more electrical interconnects 260 can be integrated such that the one or more electrical interconnects 260 are positioned to be electrically connected with at least one of the one or more electronic components 290. In an example, at least a first portion 261a of the one or more electrical interconnects 260 is coupled with, or electrically connected with the one or more electronic components 290 and a second portion 261b of the one or more electrical interconnects 160 is coupled with or electrically connected with an electrical component outside of the component cavity 270. In another example, as illustrated in FIG. 2, the first portion 261a is electrically connected with one of the one or more additively printed electrical circuits 180, the second portion 261b is electrically connected with one of the one or more electronic components 280 within the component cavity 270, and a third portion 261c is coupled with or electrically connected to the outside of the component cavity 270.

The additively manufactured electronics packaging assembly 210 can include a housing lid 258. The housing lid 258 can enclose, seal or isolate the component cavity 270 from exterior environmental materials or maintain the environment within the component cavity 270. The housing lid 258 can be coupled along the one or more additively printed walls 155 (either in a polygonal form as illustrated in FIG. 1A, 2 or rounded as illustrated in FIG. 1B). In an example, the housing lid 258 can be coupled with an adhesive, welding, soldering, additively printing or the like. For example, the housing lid 258 is an additional component for the additively manufactured electronics packaging assembly 210 that is provided separately from the unitary form of the additively manufactured electronics packaging assembly 210. The housing lid 258 can be coupled with at least one wall of the one or more additively printed walls 155 to seal the component cavity 270. In an example, the housing lid 258 is coupled with upper portions 257 of the one or more additively printed walls 155. For instance, the housing lid 258 can be coupled with interior portions 273 of the one or more additively printed walls 155.

The housing lid 258 can be coupled with the one or more additively printed walls 155 to hermetically seal the component cavity 270. In an example, the one or more additively printed electrical circuits 180 and electronic components 290 are housed within the electronics housing 150 with the housing lid 258 covering a housing opening 272, defined by the one or more additively printed walls 155, of the component cavity 270. The housing lid 258 can assist in maintaining the environment within the component cavity 270. For instance, the housing lid 258 can assist in reducing infiltration of environmental material (e.g., moisture, dust, particulates) into the component cavity 270. In an example, the housing lid 258 can reduce moisture, such as humidity, from infiltrating into the component cavity 270. In another example, the housing lid 258 can reduce electrical leakage, such as signal loss, from the one or more electronic components 280. The housing lid 258 can also assist in maintaining specific pressures within the component cavity 270. For instance, the housing lid 258 can assist in maintaining a low-pressure environment within the component cavity 270.

The housing lid 258 can be formed with additive printing as a separate component. In another example, the housing lid 258 can be formed with additive printing substantially directly on the one or more additively printed walls 155. The housing lid 258 can be formed from one or more housing lid layers 259. The one or more housing lid layers 259 can be formed from similar materials as the 155, such as ceramics, polymers, glass, metals or a combination of materials. The housing lid 258 can also be molded, extruded, machined or otherwise formed to have a profile or dimensions that corresponds with the housing opening 272.

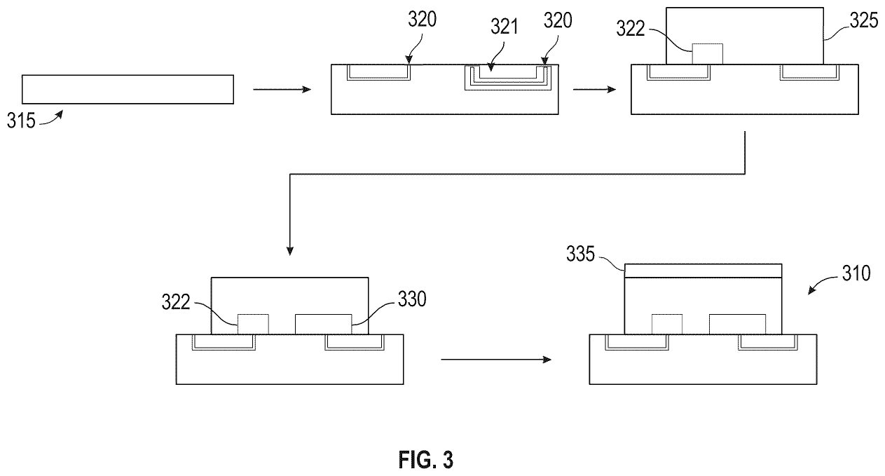

Illustrated in FIG. 3 is a schematic that illustrates an example method of forming an additively manufacture electronic package assembly 310. The method includes building a build substrate 315. Building the build substrate 315 includes depositing a first layer of a material on a build plate of an additive manufacturing system. The first layer can be deposited with one of fused deposition modeling, stereolithography, selective laser sintering or binder jetting (hereinafter additive printing). In an example, the build substrate 315 includes additively printing a stack of layers on the first layer. For instance, the stack of layers includes one or more subsequent layers with each layer having a layer interface. The layer interface can, for example, face, be bonded with a subsequent layer having a corresponding layer interface. Each of the layer interfaces can intermingle with the adjacent, or subsequent, layer interface. In an example, additional layers are added to previous layers according to a predetermined design. The one or more layers forming the stack of layers can include depositions, or printing, layers that include different materials. For example, a first layer can be ceramic, and the second layer can be a polymer. In some examples, there are one or more layers of the same material followed by one or more layers of a different material.

Optionally, while additively printing the stack of layers to form the build substrate 315, one or more electrical interconnects 320 are integrated or incorporated with the additively printed layers. In an example, the one or more interconnects 320 can include electrical traces 321 in which an electrical interconnect is positioned. In an example, the one or more electrical interconnects 320 are deposited in concert with the additively printed layers. For instance, the additively printed layer material is not deposited in locations where the additively printed one or more electrical interconnects 320 is to be positioned or printed. In an example, the one or more electrical interconnects 320 is additively printed from one or more of a metal or a conductive adhesive. The one or more electrical interconnects 320 can be printed with a first end portion and a second end portion. For example, at least one of the first end portion and the second end portion are exposed from the build substrate 315.

After the build substrate 315 is formed, or while the build substrate 315 is being formed, an additively printed electrical circuit 322 and an additively printed housing 325 are formed on the build substrate 315. For example, the additively printed housing 325 is additively printed on the build substrate 315. The additively printed housing 325 with the build substrate 315 is formed as a unitary structure. For example, the additively printed housing 325 is continuously built with the build substrate 315. The additively printed housing 325 can be formed from the same material as the build substrate 315. In another example, the additively printed housing 325 can be formed from a different material as the build substrate 315. In yet another example, the additively printed layers of the additively printed housing 325 can be different as the additively printed housing 325 is additively printed.

In an example, the additively printed housing 325 is printed from one or more additively printed walls. The additively printed walls can extend around a component cavity. For instance, the additively printed walls can define a cavity, opening, space, recess or the like. The cavity can have a dimension sized to retain one or more electronic components 330. The additively printed electrical circuit 322 can be additively printed in the component cavity. The additively printed electrical circuit 322 can be positioned to electrically contact at least one of a first portion or a second portion of the one or more electrical interconnects 320.

The one or more electronic components 330 can be positioned or retained within the component cavity to be electrically connected with at least one of a first end portion or the second end portion of the one or more electrical interconnects 320.

The additively printed housing 325 can be sealed with the additively printed electrical circuits 322 and the one or more electronic components 330 with a housing lid 335. The housing lid 335 can be coupled with the one or more of the additively printed walls. In an example, the housing lid 335 is additively printed on the one or more additively printed walls. The housing lid 335 can be a separate additively printed component that is adhered, welded, fastened or otherwise coupled with the one or more additively printed walls.

In an example, the housing lid 335 seals the component cavity when coupled with the one or more additively printed walls. For instance, the housing lid 335 isolates the components, such as the electronic components, positioned or retained within the cavity from an environment exterior to the additively manufacture electronic package assembly 310. The housing lid 335 in combination with the unitary form of the build substrate 315 with the additively printed housing 325 reduces exterior environmental material from infiltrating into the component cavity. For example, once the housing lid 335 is coupled with the one or more additively printed walls, the components are isolated from moisture, particulates, or other matter.

The housing lid 335 can also maintain the internal environment within the component cavity. In an example, the housing lid 335 can create and maintain a hermetic seal for a low-pressure environment within the component cavity. In an example, the housing lid 335 reduces moisture, such as humidity, from infiltrating into the component cavity. In an example, the additively printed electrical circuit 322 can be used to detect changes in the internal environment within the component cavity. For example, a value of a component within the electrical circuit (e.g., a resistance, a capacitance) can be calibrated according to a variance of the value with pressure, humidity, moisture, or the like. The electrical interconnects 320 can be used to measure the value of the components (e.g., the resistance, the capacitance) within the additively printed electrical circuits 322 while the housing lid 335 maintains a seal with the additively printed housing 325.

In another example, the housing lid 335 in combination with the unitary form of the build substrate 315 with the additively printed housing 325 reduces electrical signal leakage from the electrical components housed or retained within the component cavity.

The combination of the housing lid 335 adhered, printed, or otherwise coupled with the additively printed housing 325 and the additively printed housing 325 printed on the build substrate 315 reduces areas where external environmental material can infiltrate into the component cavity and also the environment within the component cavity from escaping.

Illustrated in FIG. 4 is an example of an electrical circuit diagram 400 for an electrical circuit that can be additively printed with an additively manufactured electronics packaging assembly. The electrical circuit diagram 400 can be representative of the one or more additively printed electrical circuits 180 with reference to FIGS. 1A and 2, and the additively printed electrical circuit 322 with reference to FIG. 3. That is, in an example, the electrical circuit diagram can be additively printed in a component cavity of an additively printed electronics housing. In an example, one or more components of the electrical circuit diagram 400 can be additively printed using a first electrically conductive material, and one or more other components of the electrical circuit diagram 400 can be additively printed using a second electrically conductive material. In an example, the electrical circuit diagram 400 can be an equivalent circuit diagram for an individual additively printed electrical component, such as an interdigitated capacitor as discussed with reference to FIG. 5.

The electrical circuit diagram 400 includes a resistor 402 with a value of resistance R1, a capacitor 404 with a value of capacitance C1, and a voltage source 406 with a voltage value V_{batt}. In an example, any additional electrical circuit elements (e.g., inductors, additional resistors, additional capacitors, operational amplifiers, transistors, or the like) can be present in the one or more additively printed electrical circuits 180 and 322.

The resistor 402 can have any suitable value of resistance R1. The value of resistance R1 can be a fixed value. In an example, one or more physical dimensions (e.g., length, width, etc.) of the resistor 402 can be determined such that the resistor 402 has a specified value of resistance R1 based on the one or more physical dimensions and a resistivity p of a material used in additively printing the resistor 402. In an example, the resistor 402 can represent an effective resistance of any quantity of additively printed electrical traces in the one or more additively printed electrical circuits 180 or additively printed electrical circuit 322.

The capacitor 404 can have any suitable value of capacitance C1. In an example, one or more physical dimensions of the capacitor 404 can be determined such that the capacitor 404 has a specified value of capacitance C1 based on the one or more physical dimensions and one or more dielectric constants of a material used in additively printing the capacitor 404. In an example, the capacitor 404 can be a parallel plate capacitor, where the capacitor 404 is additively printed by printing parallel electrical traces with a specified spacing. In an example, the capacitor 404 can be an interdigitated capacitor, as discussed below with reference to FIG. 5. In an example, any other geometric arrangement of additively printed electrical traces that store charge can be used for capacitor 404.

As illustrated in FIG. 4, the resistor 402 and the capacitor 404 can be connected in series. In an example, the resistor 402 and the capacitor 404 can be connected in parallel. In an example, the RC time constant tau t of the electrical circuit diagram 400 can be τ=R₁C₁, where R1 is the resistance value of the resistor 402 and C1 is the capacitance value of the capacitor 404 as described above.

At least one of the value of the resistor 402 and the value of the capacitor 404 can vary in response to a change in the ambient environment. In an example, when electrical circuit diagram 400 is an additively printed circuit such as additively printed electrical circuits 180 in the component cavity 170, the ambient environment can be a vacuum environment. When the pressure or humidity of the component cavity 170 changes (e.g., due to a leak in a seal of the additively manufactured electronics packaging assembly, operation of electrical components also in the component cavity, etc.), at least one of the value of the resistor 402 and the value of the capacitor 404 can change. In an example, the RC time constant t can change corresponding to the change in at least one of the value of the resistor 402 and the value of the capacitor 404.

In an example, the value of the resistor 402 can be described as a fixed value R1 and a change due to the change in environment, such as R=R₁+ΔR, where ΔR can be due to a change in ambient temperature, ambient pressure, humidity, or the like.

In an example, the value of the capacitor can be described as a fixed value C1 and a change due to the change in environment, such as C=C₁+ΔC, where ΔC can be due to a change in ambient temperature, ambient pressure, humidity, or the like.

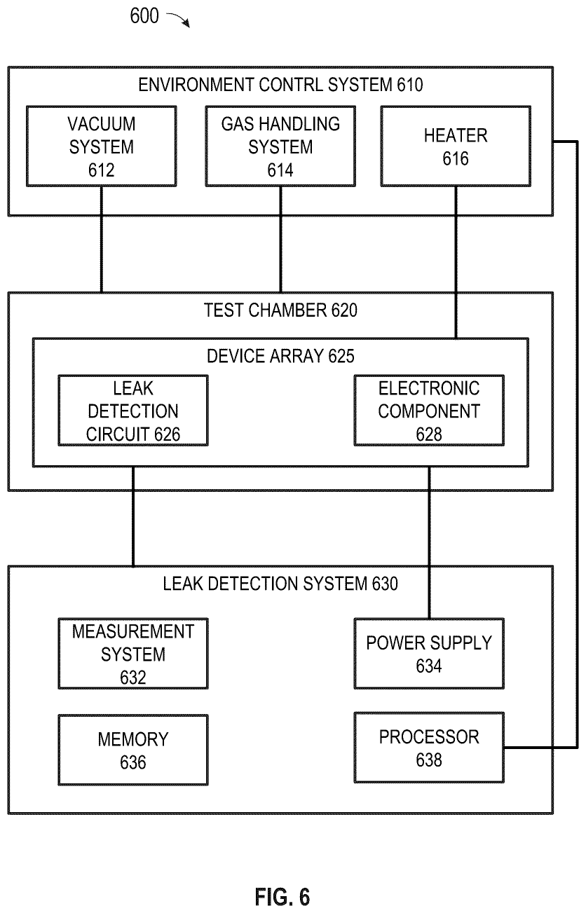

The voltage source 406 can be internal to the electronics housing. In an example, the voltage source 406 can be a battery that is included in the electronics housing, with electrical leads additively printed to electrically connect the battery to the rest of the circuitry shown in electrical circuit diagram 400. The voltage source 406 can be external to the electronics housing. In an example, voltage source 406 can be an external power source, such as a source-meter unit (SMU) that is used to measure electrical response of the electrical circuit diagram 400. For example, with reference to FIG. 6, the voltage source 406 can be included as a power supply 634 in a leak detection system 630 that is used to energize the leak detection circuit 626. The voltage source 406 can provide a static voltage (DC source) or can provide an alternating voltage (AC source).

In an example, the nodes 1 and 2 can be one or more electrical connections to one or more electrical interconnects 160. In an example, the nodes 1 and 2 can include wire traces that are additively printed to connect the components in the electrical circuit diagram 400 to one or more additional circuits (e.g., additively printed circuits, electronic components such as processors, etc.). In an example, the nodes 1 and 2 can be external to the electronics housing, such as first end portion 161a of one or more electrical interconnects 160 with reference to FIG. 1A or third portion 261c of one or more electrical interconnects 260 with reference to FIG. 2. In an example, the nodes 1 and 2 can be used to measure the value of resistance R1, the value of capacitance C1, the time constant t, or any other suitable property of the electrical circuit diagram 400. In an example, the nodes 1 and 2 can deliver one or more input signals, such as frequency swept voltage, to the electrical circuit in electrical circuit diagram 400. In an example, nodes 1 and 2 can be positioned at any location other than that shown in FIG. 4. For example, nodes 1 and 2 can be incorporated into the voltage source 406 as part of a device-under-test electrical characterization of the additively printed electrical circuit.

The voltage source 406 and the nodes 1 and 2 can be used to measure the resistance value of the resistor 402, the capacitance value of the capacitor 404, or both values (e.g., based on a measurement of the time constant t). In an example, a change in environment (e.g., of the component cavity 170) can be detected based on a change in one or more measured values, as discussed further with reference to FIG. 6.

Illustrated in FIG. 5 is an example of an interdigitated capacitor (IDC) 500 that can be additively printed as an electrical component in an additively printed electrical circuit. In an example, the IDC 500 can be a schematic for an additively printed capacitor such as the capacitor 404 in the electrical circuit diagram 400 as discussed above with reference to FIG. 4.

In the illustration of FIG. 5, aspects of the IDC 500 which are described as being joined to another aspect of the IDC 500 can be understood to be electrically conducting between the joined aspects.

The IDC 500 can have a first plate 501 positioned in parallel to a second plate 505. The IDC 500 can have a first electrical lead 510 that is joined to the first plate 501. The IDC can have a second electrical lead 520 that is joined to the second plate 505.

The IDC 500 can have one or more fingers 502 that are joined to and extend from one of the first plate 501 or the second plate 505 towards the other plate. For example, FIG. 5 illustrates two fingers 502 on each of the first plate 501 and the second plate 505. The fingers 502 can be alternating such that a finger 502 joined to (and extending from) the first plate 501 can be followed by a finger 502 joined to (and extending from) the second plate 505. Although two fingers 502 are shown on each of the first plate 501 and the second plate 505, any quantity of fingers 502 can be included on the first plate 501 and the second plate 505, as shown by the continuation indicator (three dots) illustrated in FIG. 5.

The IDC 500 can have one or more dimensional values for the arrangement of the first plate 501, the second plate 505, and the fingers 502. In an example, dimension A illustrated in FIG. 5 can be a separation in a first direction between an end of one finger 502 and a side of the plate opposing the finger 502 (e.g., not connected to the finger 502). In an example, dimension B illustrated in FIG. 5 can be a separation in a second direction (e.g., different from the first direction) between adjacent fingers 502. The separation between adjacent fingers 502 can be denoted by a center-to-center distance. The separation between adjacent fingers 502 can be denoted by an edge-to-edge distance, as shown by dimension B in FIG. 5. The separation of adjacent fingers 502 can be uniform throughout the IDC 500.

In an example, dimension 1 illustrated in FIG. 5 can be a first print dimension such as a length of the fingers 502 as extending from the respective one of the first plate 501 or the second plate 505. In an example, the extension length of the fingers can be uniform throughout the IDC 500. In an example, dimension 2 illustrated in FIG. 5 can be a second print dimension such as a width of an individual finger 502. In an example, dimension 3 can be a third print dimension such as a width of the first plate 501. In an example, the width of the second plate 505 can be approximately the same as the width of the first plate 501 (e.g., dimension 3).

A dielectric material can fill the space between the plates 501 and 505 and fingers 502 of the IDC. In an example, the build substrate 120 can be the dielectric material of the IDC 500, as the IDC 500 can be additively printed on the surface 125 of the build substrate 120.

The capacitance of the IDC 500 can be determined according to the geometric arrangement of the two parallel plates 501 and 505 and the fingers 502. In an example, the capacitance C of the IDC 500 can be

$$C = ( {ϵ}_{r} + 1 ) * L * ( ( N - 3 ) * {A}_{1} + {A}_{2} )$$

where ϵᵣ is the dielectric constant of the build substrate 120, L is a value of the dimension 1, N is the quantity of fingers in the IDC 500, and A₁ and A₂ are area factors determined by the build substrate 120 (e.g., depth of the material) and dimension 2 of the fingers. In an example, the IDC 500 can be designed using computer aided design programs, and a model of the IDC 500 can be used in a physics simulation to determine the capacitance C.

Illustrated in FIG. 6 is a system 600 for detecting degradation of a hermetic seal in an additively manufactured electronics packaging assembly. In an example, the system 600 includes an environmental control system 610, a test chamber 620, and a leak detection system 630.

Leaks can arise in an additively manufactured electronics packaging assembly such as additively manufactured electronics packaging assembly 210. For example, a leak may form where the housing lid 258 is coupled with at least one wall of the one or more additively printed walls 155 to seal the component cavity 270. When an electronic component 290 inside the component cavity 270 is powered on or otherwise used, the electronic component 290 can increase a temperature of the component cavity 270 (e.g., due to operational waste heat of the electronic component 290). When the temperature of the component cavity 270 increases, any gas inside the component cavity 270 becomes pressurized and can be forced out of the component cavity 270 through the leaks. When the electronic component 290 is switched off, there can be a corresponding drop in internal pressure of the component cavity. Leaky operation of an additively manufactured electronics packaging assembly 210 can cause unreliable operation of the electronic component 290. Leak testing using a system such as system 600 can provide a quantified measurement of leak rates of the additively manufactured electronics packaging assembly 210.

The environmental control system 610 can be used in combination with the test chamber 620 to provide a specified environment exterior to the packaging assembly 210 to induce pressure changes within the component cavity 270. The packaging assembly 210 can be part of an array of such devices (e.g., device array 625), and a leak detection circuit 626 within a given packaging assembly can be used to sense an induced pressure change within the component cavity 270 of the given packaging assembly. The leak detection circuit 626 can be powered and operated by the leak detection system 630 which can measure one or more electrical properties of the leak detection circuit 626.

The environmental control system 610 can include a vacuum system 612, a gas handling system 614, and a heater 616. The vacuum system 612 can be connected to the test chamber 620 through one or more pipes, flanges, valves, or the like. The vacuum system 612 can include one or more pumps, such as to create a low pressure environment (e.g., rough vacuum, high vacuum, ultra-high vacuum) in the test chamber 620. The gas handling system 614 can include any suitable species of atomic or molecular gasses, such as nitrogen, argon, helium, krypton, or the like. The gas handling system 614 can be connected to the test chamber 620 through one or more pipes, flanges, valves, or the like. The gas handling system can create a partial pressure environment in the test chamber 620 with a specified gas species at a specified partial pressure. The heater 616 can include any suitable heating element, such as an inductive heater, a resistive heater, or the like. The heater 616 can include a thermometer so as to record a temperature at a surface of the heater 616. The heater 616 can be configured to deliver heat energy to one or more devices in the test chamber 620.

The test chamber 620 can be configured to hold a device array 625 interior to the test chamber 620 while allowing electrical signals to be delivered to one or more devices in the device array 625. That is, the test chamber 620 can include one or more electrical feedthroughs which can terminate at the device array inside the test chamber. The device array 625 can include one or more additively manufactured electronics packaging assembly such as additively manufactured electronics packaging assembly 210. In an example, the device array 625 can configure the one or more additively manufactured electronics packaging assembly for batch testing one or more electronic componentry sealed within each one of the one or more additively manufactured electronics packaging assembly. That is, in an example, the device array 625 can include a breadboard, break-out board, or the like, such that multiple devices in the device array 625 can be electrically connected to one or more electrical feedthroughs in the test chamber 620.

A given additively manufactured electronics packaging assembly in the device array 625 can have a leak detection circuit 626 and an electronic component 628. In an example, the leak detection circuit 626 can be an additively printed electrical circuit such as one or more additively printed electrical circuits 180 or additively printed electrical circuit 322. In an example, the electronic component 628 can be added to a component cavity of the additively manufactured electronics packaging assembly before the component cavity is sealed. In an example, the electronic component 628 can be any type of analog or digital electronic component. In an example, the electronic component 628 can be a memory device, a storage device, a processing device, a logic device, or the like.

The leak detection system 630 can include a measurement system 632, a power supply 634, a memory 636, and a processor 638. The leak detection system 630 can measure electrical properties of the leak detection circuit 626. For example, the leak detection system 630 can connect to an exterior side of the electrical feedthroughs of the test chamber 620 to deliver electrical signals to the leak detection circuit 626. In an example, the leak detection system 630 can be configured to track the measured electrical properties as different environmental parameters are applied to the devices in the device array 625.

The measurement system 632 can include one or more electrical test instruments that are configured to measure a value of a resistance, a capacitance, a time constant, or the like, in the leak detection circuit 626. The measurement system 632 can include a voltmeter, an ammeter, an inductance meter, a lock-in amplifier, feedback controls (e.g., P-I-D circuitry), one or more signal conditioning circuits, or the like. In an example, the measurement system 632 can connect to the electrical component 628, such as to test an electrical property of the electrical component 628 under varying environmental conditions. The power supply 634 can include a power source for the electrical component 628.

The memory 636 can include static memory, dynamic memory, or the like. The memory 636 can be configured to store measurements (e.g., data) from the measurement system 632. The processor 638 can be configured to execute instructions that cause the measurement system 632 to collect measurements on the value of a resistance, a capacitance, a time constant, or the like, in the leak detection circuit 626. The processor 638 can compare a value of a measurement from the measurement system 632 with one or more reference values (e.g., calibration curves or the like). The processor 638 can determine a value of pressure interior to the device (e.g., in a component cavity of an additively manufactured electronics packaging assembly) based on the measurement from the measurement system 632.

The processor 638 can further determine a measured leak rate based on the determined pressure interior to the device. The processor 638 can be configured to determine a range of values for acceptable leak rates, and the processor 638 can determine if the measured leak rate is within the range of values for acceptable leak rates. For example, the specifications according to any of MIL 883, BS9000, IEC749, MIL 202F, or the like, can be used to configure the process 638 to determine if the measured leak rate indicates that the additively manufactured electronics housing assembly remains sealed or is leaking.

The processor 638 can be further configured to cause the environmental control system 610 (e.g., the vacuum system 612 or the gas handling system 614) to produce one or more pressures (e.g., a vacuum level, a partial pressure with a specified gas species) in the test chamber 620.

### Aspects

Aspect 1 can include subject matter such as an additively manufactured electronics packaging assembly comprising: a build substrate including: one or more additively printed insulating layers; and additively printed electrical interconnects positioned within the one or more additively printed insulating layers including a first end portion and a second end portion; and an electronics housing coupled along the build substrate, the electronics housing includes: additively printed walls extending around a component cavity; a housing lid coupled along the additively printed walls and enclosing the component cavity; and one or more additively printed electrical circuits within the component cavity, the one or more additively printed electrical circuits electrically connected with at least one of the additively printed electrical interconnects; and wherein the additively printed walls and the housing lid of the electronics housing are configured to seal the component cavity from an environment exterior to the electronics housing; wherein the one or more additively printed electrical circuits are configured to produce a change an electrical characteristic that indicates a leak rate in the additively manufactured electronics packaging assembly.

Aspect 2 can include, or optionally be combined with the subject matter of Aspect 1, to optionally include the one or more additively printed electrical circuits includes a resistive component for use in indicating the leak rate in the additively manufactured electronics packaging assembly.

Aspect 3 can include, or optionally be combined with the subject matter of one or any combination of Aspects 1 or 2 to optionally include the change in the electrical characteristic comprises a change in a value of resistance of the resistive component in response to a change in an environment interior to the electronics housing.

Aspect 4 can include, or optionally be combined with the subject matter of one or any combination of Aspects 1 to 3 to optionally include the change in the electrical characteristic comprises, in response to a change in an environment interior to the electronics housing, a change in a value of an RC time constant of the one or more additively printed electrical circuits.

Aspect 5 can include, or optionally be combined with the subject matter of one or any combination of Aspects 1 to 4 to optionally include the electronics housing includes one or more electronic components within the component cavity, the one or more electrical components electrically connected with the additively printed electrical interconnects.

Aspect 6 can include, or optionally be combined with the subject matter of one or any combination of Aspects 1 to 5 to optionally include the one or more additively printed electrical circuits and at least one of the additively printed insulating layers, the additively printed electrical interconnects, or the additively printed walls are additively printed in concert.

Aspect 7 can include, or optionally be combined with the subject matter of one or any combination of Aspects 1 to 6 to optionally include each of the one or more additively printed insulating layers and the housing lid includes at least one of a ceramic, a glass, and a polymer.

Aspect 8 can include, or optionally be combined with the subject matter of one or any combination of Aspects 1 to 7 to optionally include the housing lid is at least one of: coupled with the one or more additively printed walls with an adhesive; or additively printed on the one or more additively printed walls.

Aspect 9 can include, or optionally be combined with the subject matter of one or any combination of Aspects 1 to 8 to optionally include the one or more additively printed electrical interconnects is integrated with the additively printed insulating layers.

Aspect 10 can include, or optionally be combined with the subject matter of one or any combination of Aspects 1 to 9 to optionally include the first end portion of the one or more additively printed electrical interconnects is positioned within the electronics housing and the second end portion of the one or more additively printed electrical interconnects is positioned outside of the electronics housing.

Aspect 11 can include subject matter such as a system for detecting degradation of a hermetic seal in an additively manufactured electronics packaging assembly, the system comprising: leak detection circuitry configured to: receive an additively manufactured electronics packaging assembly comprising an additively printed electronics housing that seals one or more electronic components and one or more additively printed electrical circuits in a component cavity of the additively printed electronics housing; and measure an electrical characteristic of the one or more additively printed electrical circuits; and processing circuitry configured to: determine an environmental parameter based on the electrical characteristic, the environmental parameter representative of an environment interior to the additively printed electronics housing; compare the environmental parameter to one or more criterion; and based on the comparison, determine that the additively manufactured electronics packaging assembly remains sealed.

Aspect 12 can include, or optionally be combined with the subject matter of Aspect 11 to optionally include the processing circuitry is configured to, based on the comparison, determine that the additively manufactured electronics packaging assembly is leaking.

Aspect 13 can include, or optionally be combined with the subject matter of one or any combination of Aspects 11 or 12 to optionally include the additively manufactured electronics packaging assembly is subjected to a hermetic seal test comprising placing the additively manufactured electronics packaging assembly in an environmental chamber that is pressurized with a tracer gas at a specified temperature.

Aspect 14 can include, or optionally be combined with the subject matter of one or any combination of Aspects 1 to 13 to optionally include the electrical characteristic comprises a change in a value of resistance of a resistive component during the hermetic seal test.

Aspect 15 can include, or optionally be combined with the subject matter of one or any combination of Aspects 11 to 14 to optionally include the electrical characteristic comprises a change in a value of an RC time constant during the hermetic seal test.

Aspect 16 can include, or optionally be combined with the subject matter of one or any combination of Aspects 11 to 15 to optionally include the leak detection circuitry is configured for a plurality of additively manufactured electronics packaging assemblies and wherein the processing circuitry is configured to determine a separate environmental parameter for each packaging assembly in the plurality of additively manufactured electronics packaging assemblies.

Aspect 17 can include, or optionally be combined with the subject matter of one or any combination of Aspects 11 to 16 to optionally include the leak detection circuitry is further configured to operate the one or more electronic components, and wherein operation of the one or more electronic components produces a change in an environment interior to the electronics housing.

Aspect 18 can include, or optionally be combined with the subject matter of one or any combination of Aspects 11 to 17 to optionally include the additively manufactured electronics packaging assembly further comprises: a build substrate including; one or more additively printed insulating layers; and additively printed electrical interconnects positioned within the one or more additively printed insulating layers including a first end portion and a second end portion; and the additively printed electronics housing coupled along the build substrate, the additively printed electronics housing further includes: additively printed walls extending around the component cavity; and a housing lid coupled along the additively printed walls and enclosing the component cavity; and the one or more additively printed electrical circuits electrically connected with the additively printed electrical interconnects; and wherein the one or more additively printed walls and the housing lid of the electronics housing are configured to seal the component cavity from an environment exterior to the electronics housing.

Aspect 19 can include subject matter such as a method of forming an additively manufactured electronics packaging assembly, the method comprising: forming a build substrate including: depositing a first layer of a material on a build plate; additively printing a stack of layers on the first layer; wherein the stack of layers includes one or more subsequent layers, each subsequent layer including a layer interface, the layer interface configured to be intermingled with a layer interface of a subsequent layer of the one or more subsequent layers; and while additively printing the stack of layers, additively printing one or more electrical interconnects within the stack of layers, each of the one or more the electrical interconnects including a first end portion and a second end portion; additively printing an electronics housing along the build substrate and continuously with the build substrate, wherein additively printing the electronics housing comprises: depositing one or more wall layers on the build substrate to form a printed wall extending around a component cavity; and additively printing one or more electrical circuits within the component cavity, the one or more electrical circuits electrically connected to the electrical interconnects, wherein at least one component in the one or more electrical circuits is responsive to a change in an environment interior to the electronics housing; and sealing the electronics housing with a housing lid by coupling the housing lid with one or more printed walls.

Aspect 20 can include, or can optionally be combined with the subject matter of Aspect 19, to optionally include positioning one or more electronic components within the component cavity; electrically connecting the one or more electronic components with at least one of the first end portion or the second end portion of the one or more electrical interconnects; and sealing the one or more electronic components within the component cavity, including: isolating the one or more electronic components from an environment exterior to the electronics housing.

The above description includes references to the accompanying drawings, which form a part of the detailed description. The drawings show, by way of illustration, specific embodiments in which the disclosed concepts can be practiced. These embodiments are also referred to herein as “aspects” or “examples.” Such aspects or example can include elements in addition to those shown or described. However, the description also contemplates aspects or examples in which only those elements shown or described are provided. Moreover, the description also contemplates aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel,” “perpendicular,” “round,” or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, subject matter may lie in less than all features of a particular disclosed embodiment. Thus, the following claims are hereby incorporated into the Detailed Description as aspects, examples, or embodiments, with each claim standing on its own as a separate embodiment, and it is contemplated that such embodiments can be combined with each other in various combinations or permutations. The scope of the disclosed concepts should be determined with reference to the appended claims, along with the full scope of equivalents to which such claims are entitled.

What is claimed is:

1. An additively manufactured electronics packaging assembly comprising:
a build substrate including:
one or more additively printed insulating layers; and
additively printed electrical interconnects positioned within the one or more additively printed insulating layers including a first end portion and a second end portion; and
an electronics housing coupled along the build substrate, the electronics housing includes:
additively printed walls extending around a component cavity;
a housing lid coupled along the additively printed walls and enclosing the component cavity; and
one or more additively printed electrical circuits within the component cavity, the one or more additively printed electrical circuits electrically connected with at least one of the additively printed electrical interconnects; and wherein the additively printed walls and the housing lid of the electronics housing are configured to seal the component cavity from an environment exterior to the electronics housing;
wherein the one or more additively printed electrical circuits are configured to produce a change an electrical characteristic that indicates a leak rate in the additively manufactured electronics packaging assembly.

2. The additively manufactured electronics packaging assembly of claim 1, wherein the one or more additively printed electrical circuits includes a resistive component for use in indicating the leak rate in the additively manufactured electronics packaging assembly.

3. The additively manufactured electronics packaging assembly of claim 2, wherein the change in the electrical characteristic comprises a change in a value of resistance of the resistive component in response to a change in an environment interior to the electronics housing.

4. The additively manufactured electronics packaging assembly of claim 2, wherein the change in the electrical characteristic comprises, in response to a change in an environment interior to the electronics housing, a change in a value of an RC time constant of the one or more additively printed electrical circuits.

5. The additively manufactured electronics packaging assembly of claim 1, wherein the electronics housing includes one or more electronic components within the component cavity, the one or more electrical components electrically connected with the additively printed electrical interconnects.

6. The additively manufactured electronics packaging assembly of claim 1, wherein the one or more additively printed electrical circuits and at least one of the additively printed insulating layers, the additively printed electrical interconnects, or the additively printed walls are additively printed in concert.

7. The additively manufactured electronics packaging assembly of claim 1, wherein each of the one or more additively printed insulating layers and the housing lid includes at least one of a ceramic, a glass, and a polymer.

8. The additively manufactured electronics packaging assembly of claim 1, wherein the housing lid is at least one of:
coupled with the one or more additively printed walls with an adhesive; or
additively printed on the one or more additively printed walls.

9. The additively manufactured electronics packaging assembly of claim 1, wherein the one or more additively printed electrical interconnects is integrated with the additively printed insulating layers.

10. The additively manufactured electronics packaging assembly of claim 1, wherein the first end portion of the one or more additively printed electrical interconnects is positioned within the electronics housing and the second end portion of the one or more additively printed electrical interconnects is positioned outside of the electronics housing.

11. A system for detecting degradation of a hermetic seal in an additively manufactured electronics packaging assembly, the system comprising:
leak detection circuitry configured to:
receive an additively manufactured electronics packaging assembly comprising an additively printed electronics housing that seals one or more electronic components and one or more additively printed electrical circuits in a component cavity of the additively printed electronics housing; and
measure an electrical characteristic of the one or more additively printed electrical circuits; and
processing circuitry configured to:
determine an environmental parameter based on the electrical characteristic, the environmental parameter representative of an environment interior to the additively printed electronics housing;
compare the environmental parameter to one or more criterion; and
based on the comparison, determine that the additively manufactured electronics packaging assembly remains sealed.

12. The system of claim 11, wherein the processing circuitry is configured to, based on the comparison, determine that the additively manufactured electronics packaging assembly is leaking.

13. The system of claim 11, wherein the additively manufactured electronics packaging assembly is subjected to a hermetic seal test comprising placing the additively manufactured electronics packaging assembly in an environmental chamber that is pressurized with a tracer gas at a specified temperature.

14. The system of claim 13, wherein the electrical characteristic comprises a change in a value of resistance of a resistive component during the hermetic seal test.

15. The system of claim 13, wherein the electrical characteristic comprises a change in a value of an RC time constant during the hermetic seal test.

16. The system of claim 11, wherein the leak detection circuitry is configured for a plurality of additively manufactured electronics packaging assemblies and wherein the processing circuitry is configured to determine a separate environmental parameter for each packaging assembly in the plurality of additively manufactured electronics packaging assemblies.

17. The system of claim 11, wherein the leak detection circuitry is further configured to operate the one or more electronic components, and wherein operation of the one or more electronic components produces a change in an environment interior to the electronics housing.

18. The system of claim 11, wherein the additively manufactured electronics packaging assembly further comprises:
a build substrate including;
one or more additively printed insulating layers; and
additively printed electrical interconnects positioned within the one or more additively printed insulating layers including a first end portion and a second end portion; and
the additively printed electronics housing coupled along the build substrate, the additively printed electronics housing further includes:
additively printed walls extending around the component cavity; and
a housing lid coupled along the additively printed walls and enclosing the component cavity; and
the one or more additively printed electrical circuits electrically connected with the additively printed electrical interconnects; and wherein the one or more additively printed walls and the housing lid of the electronics housing are configured to seal the component cavity from an environment exterior to the electronics housing.

19. A method of forming an additively manufactured electronics packaging assembly, the method comprising:
forming a build substrate including:
depositing a first layer of a material on a build plate;
additively printing a stack of layers on the first layer;
wherein the stack of layers includes one or more subsequent layers,
each subsequent layer including a layer interface, the layer interface configured to be intermingled with a layer interface of a subsequent layer of the one or more subsequent layers; and
while additively printing the stack of layers, additively printing one or more electrical interconnects within the stack of layers, each of the one or more the electrical interconnects including a first end portion and a second end portion;
additively printing an electronics housing along the build substrate and continuously with the build substrate, wherein additively printing the electronics housing comprises:
depositing one or more wall layers on the build substrate to form a printed wall extending around a component cavity; and
additively printing one or more electrical circuits within the component cavity, the one or more electrical circuits electrically connected to the electrical interconnects, wherein at least one component in the one or more electrical circuits is responsive to a change in an environment interior to the electronics housing; and
sealing the electronics housing with a housing lid by coupling the housing lid with one or more printed walls.

20. The method of forming the additively manufactured electronics packaging assembly of claim 19, including:
positioning one or more electronic components within the component cavity;
electrically connecting the one or more electronic components with at least one of the first end portion or the second end portion of the one or more electrical interconnects; and
sealing the one or more electronic components within the component cavity, including:
isolating the one or more electronic components from an environment exterior to the electronics housing.
